(19) United States
(12) Patent Application Publication
(10) Pub. No.: US 2018/0226531 A1
(43) Pub. Date: Aug. 9, 2018

(54) OPTOELECTRONIC DEVICE HAVING PHOTODIODES FOR DIFFERENT WAVELENGTHS AND PROCESS FOR MAKING SAME

(71) Applicant: PixArt Imaging Incorporation, Hsin-Chu (TW)

(72) Inventors: Sen-Huang Huang, Hsin-Chu (TW); Hsin-Hui Hsu, Hsin-Chu (TW); Nien-Tse Chen, Hsin-Chu (TW)

(21) Appl. No.: 15/942,536

(22) Filed: Apr. 1, 2018

Related U.S. Application Data
(62) Division of application No. 14/321,240, filed on Jul. 1, 2014.
Application No. 14/321,240 is a continuation-in-part of application No. 12/552,856, filed on Sep. 2, 2009, now abandoned.

(51) Int. Cl. H01L 31/18; H01L 21/02; H01L 27/146; H01L 31/103

(52) U.S. Cl. CPC H01L 31/1812; H01L 21/02529; H01L 21/02532; H01L 21/0262; H01L 27/14645; H01L 27/14643; H01L 27/14683; H01L 21/02658; H01L 21/02381; Y02E 10/50; H01L 31/103

(57) ABSTRACT

An optoelectronic device includes: a substrate made of a first material; a region in the substrate, the region being made of a second material different from the first material; an N-well in the region made of the second material; and a photo diode formed in the region by ion implantation. The second material for example is silicon germanium (Si₁₋ₓGeₓ) or silicon carbide (Si_{1-y}C_{y}), wherein 0<x, y<1.

### CROSS REFERENCE

The present invention is a continuation-in-part application of U.S. Ser. No. 12/552,856, filed on Sep. 2, 2009.

### BACKGROUND OF THE INVENTION

### Field of Invention

The present invention relates to an optoelectronic device and a process for making same; particularly, it relates to an optoelectronic device having photodiodes for different wavelengths, and a process for making same.

### Description of Related Art

An optoelectronic device, such as a sensor, is often required in digital image processing. The sensor generally includes a photo diode and an electronic circuit, and an image received is converted to an electronic signal output.

Conventionally, a photo diode is constituted by a PN junction formed in a silicon substrate. However, such photo diode formed by silicon has low light absorption efficiency to invisible light. Accordingly, it is desired to provide a device having better light absorption efficiency for invisible light applications, such as infrared sensor.

### SUMMARY OF THE INVENTION

In one perspective, the present invention provides an optoelectronic device comprising: a substrate made of a first material; a region in the substrate, the region being made of a second material different from the first material; an N-well in the region made of the second material; and a photo diode for a first wavelength formed in the N-well.

The second material in the region for example includes silicon germanium (Si₁₋ₓGeₓ) or silicon carbide (Si_{1-y}C_{y}), wherein 0<x,y<1. The optoelectronic device can further comprise an electronic circuit coupled to the photo diode.

In one embodiment, the optoelectronic device further comprises another photodiode for a second wavelength formed in the substrate and not in the region made of the second material. In one embodiment, the first wavelength is an invisible light wavelength and the second wavelength is a visible light wavelength.

In another perspective, the present invention provides a sensor pixel unit comprising at least one photodiode for visible light and at least one photodiode for invisible light.

In one embodiment, the sensor pixel unit comprises three photodiodes for red, green and blue, and one photodiode for infrared.

In another perspective, the present invention provides a process for making an optoelectronic device, comprising: providing a substrate made of a first material; etching a region of the substrate; filling the region with a second material different from the first material; forming an N-well in the region made of the second material; and forming a photo diode in the region made of the second material.

In the foregoing process for making the optoelectronic device, preferably, the second material filled in the region includes silicon germanium (Si₁₋ₓGeₓ) or silicon carbide (Si_{1-y}C_{y}), wherein 0<x,y<1. The step of filling the region with the second material for example is epitaxial growth.

In addition, the process can further comprise: forming a masking layer to define the region before etching it; and after the region is filled with the second material, removing the masking layer. The masking layer for example includes oxide.

The process can further comprise forming another photodiode for a second wavelength in the substrate and not in the region made of the second material, wherein the first wavelength is for example an invisible light wavelength and the second wavelength is for example a visible light wavelength.

The objectives, technical details, features, and effects of the present invention will be better understood with regard to the detailed description of the embodiments below, with reference to the drawings.

### BRIEF DESCRIPTION OF THE DRAWINGS

FIGS. 1-7 show an embodiment of the present invention.

FIG. 8 shows a layout arrangement including photodiodes for visible lights and invisible light.

FIGS. 9-10 show a process for making a photodiode for visible light.

FIGS. 11-17 show another embodiment of the present invention.

### DESCRIPTION OF THE PREFERRED EMBODIMENTS

The drawings as referred to throughout the description of the present invention are for illustration only, to show the interrelationships between the process steps and between the layers, but not drawn according to actual scale.

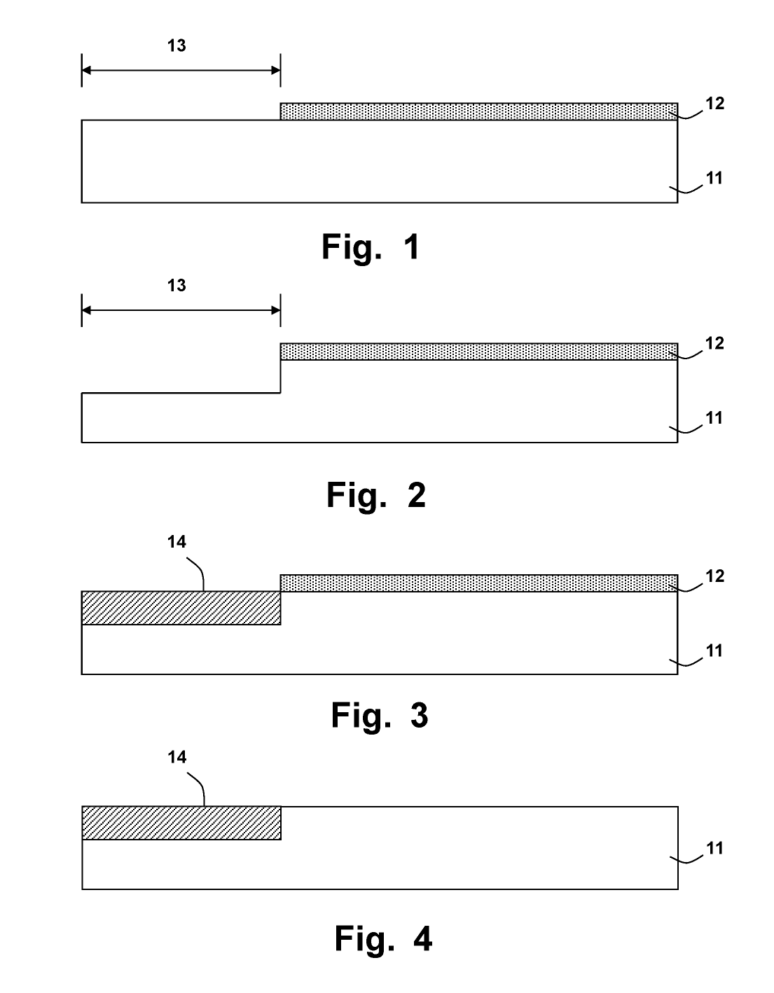

FIGS. 1-7 illustrate an embodiment of the present invention. Referring to FIG. 1, a substrate 11 made of a first material, such as silicon, is provided. A masking layer 12 is formed on the substrate 11 (e.g., by deposition); the masking layer 12 is made of a material such as oxide (e.g., silicon dioxide). The masking layer 12 has a pattern defined by photolithography and etch to expose a region 13. Next, as shown in FIG. 2, the substrate 11 is etched in accordance with the pattern of the masking layer 12. And next, referring to FIG. 3 and FIG. 4, a material layer 14 made of a second material different from the first material of the substrate 11, is formed in the etched region 13 of the substrate 11, and then the masking layer 12 is removed. According to the present invention, the material layer 14 for example can be made of a material such as silicon germanium (Si₁₋ₓGeₓ) or silicon carbide (Si_{1-y}C_{y}), wherein 0<x,y<1.

Silicon germanium for example can be formed by epitaxial growth, with primary reaction gases of (SiH₄+GeH₄), wherein SiH₄ can be replaced by SiH₂Cl₂ or SiCl₄. Other than the primary reaction gases, additional gas (es) such as SiCH₆, C₂H₄, or C₅H₈ may be added, such that the formed silicon germanium may contain a slight amount of carbon ingredient; or, additional HCl can be added, so as to enhance the selectivity of the epitaxial growth. Depending on the selected reaction gases, the epitaxial growth can be performed in a temperature for example between 550-900° C. Due to the shielding effect of the masking layer 12, the silicon germanium made by epitaxial growth can be selectively formed in the region as shown in the drawing.

Silicon carbide for example can be formed by CVD (chemical vapor deposition) epitaxial growth, with primary reaction gases of silicon-containing gas and carbon-containing gas. The former for example can be SiH₄, SiH₂Cl₂, or SiCl₄; the latter for example can be CH₄, SiCH₆, C₂H₄, or C₅H₈. The reaction temperature is between 1400-1600° C. and the reaction pressure is between 0.1 to 1 atmospheric pressure. If silicon carbide can not be selectively deposited in the desired region, photolithography and etch steps may be taken to define the pattern of the silicon carbide layer, and the masking layer 12 can be employed as an etch stop layer.

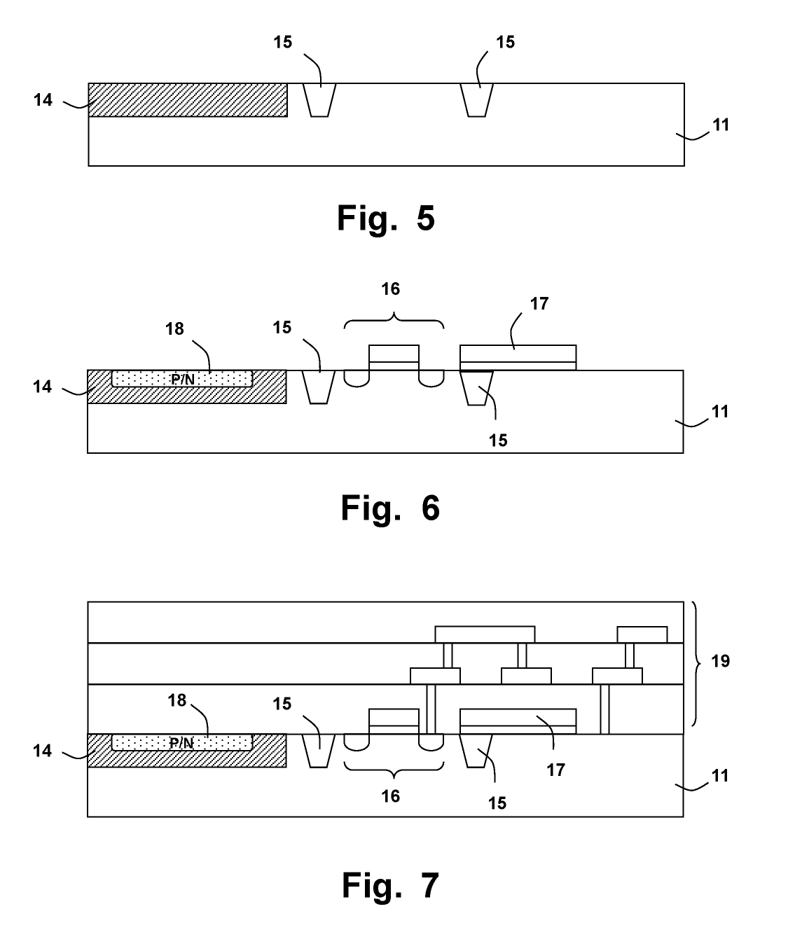

Referring to FIG. 5, an isolation region 15 such as shallow trench isolation can be formed between electronic devices in the substrate 11; the isolation region for example can be made of a material including silicon oxide. Next referring to FIG. 6, a transistor 16 and other electronic devices 17 (e.g., a resistor) are formed subsequently. In the process of forming the transistor 16, or by an additional ion implantation step, a PN junction can be formed in the material layer 14 so as to form a photo diode 18. Referring to FIG. 7, interconnection 19 is further formed to complete an integrated device including a photo diode and an electronic circuit, wherein the electronic circuit is coupled to the photo diode for processing electronic signals generated when the photo diode receives light. Subsequently, passivation layer, bond pad, package, and other steps may be taken, which are omitted here.

An essential difference of the present invention from the prior art is that the photo diode 18 of the present invention is formed in a material layer 14 having a different property from the substrate layer 11. Therefore, the present invention has better absorption efficiency to light with different wavelengths. The photo diode 18 of the prior art is formed in silicon, having an energy gap of about 1.1 eV. In the first example of the present invention, silicon germanium has an energy gape of around 0.6-1.1 eV, which has better absorption efficiency to a light beam with long wavelength (such as above 800 nm). In the second example, silicon carbide has an energy gap higher than 3 eV, which has better absorption efficiency to a light beam with short wavelength (such as below 450 nm). In other words, according to the present invention, the material of the material layer 14 can be selected in accordance with the primary wavelength of a photo signal desired to be received, so as to enhance light absorption efficiency. For example, an infrared sensor can be made by employing silicon germanium. In addition, the present invention is not limited to providing only one type of photo diodes in one integrated device; for example, photo diodes can be formed in both the material layer 14 and the substrate 11, so that one integrated device include two or more different types of photo diodes.

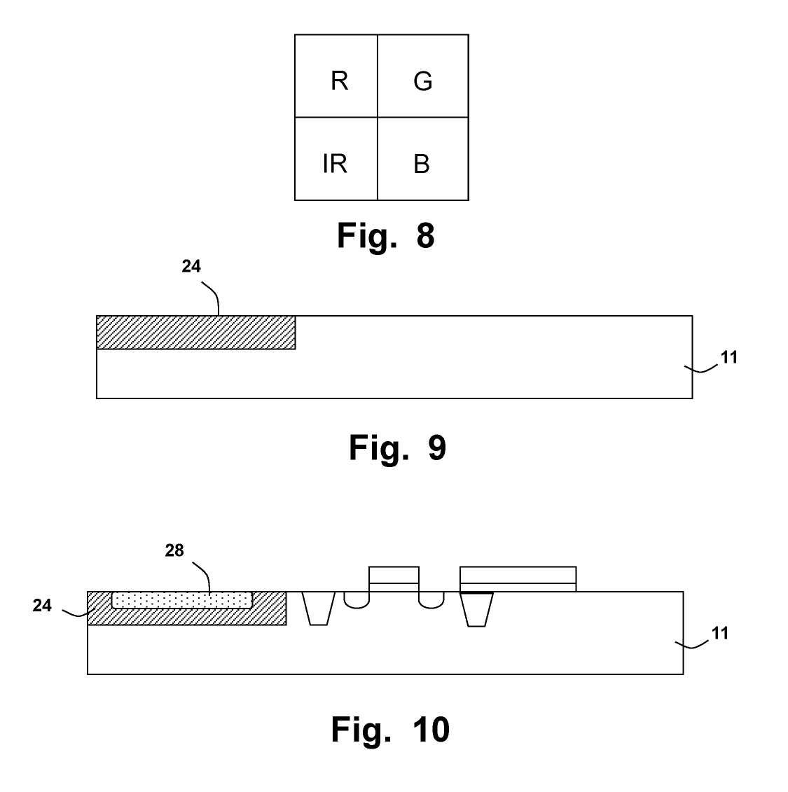

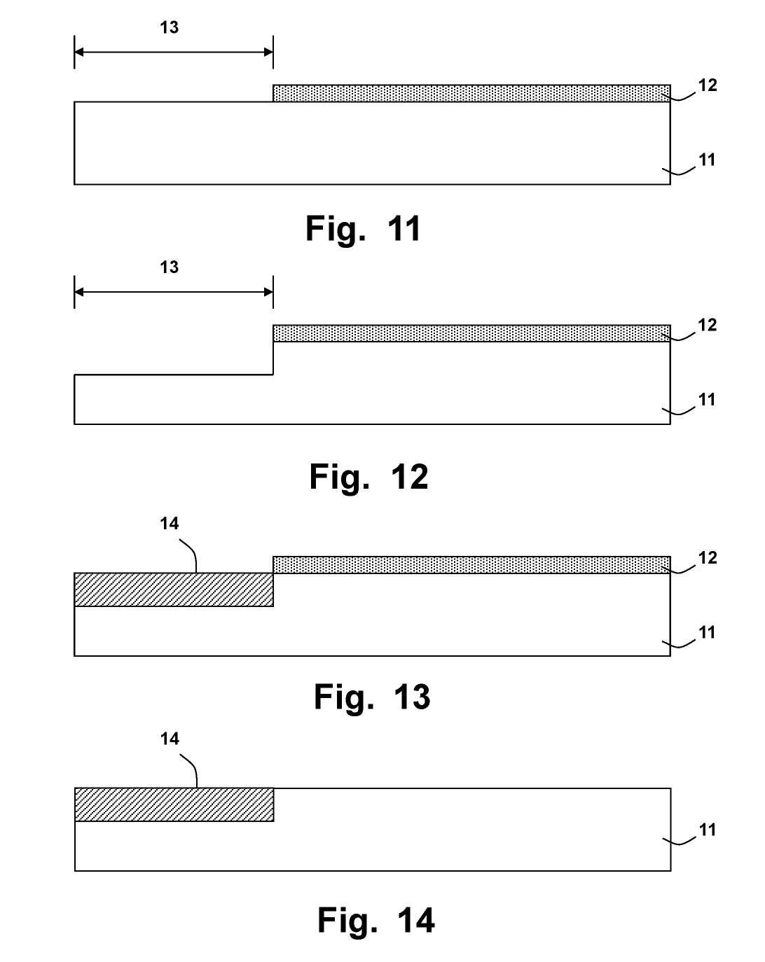

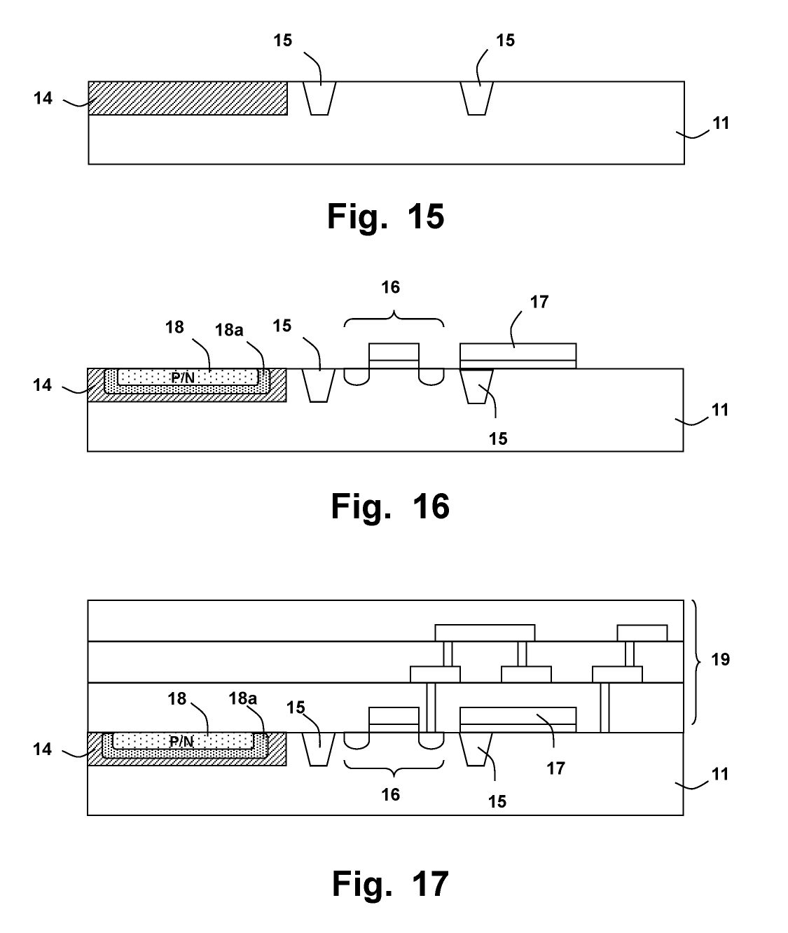

FIG. 8 shows an example that one integrated device include two or more different types of photo diodes. In the shown example, one sensor pixel unit includes three photodiodes for three visible light wavelengths red, green and blue (R, G and B) and one photodiode for invisible light infrared (IR). Note that the layout is only for example; the locations of the photodiodes can be arranged differently (for example, the locations of the red and green can be interchanged). The photodiode IR can be formed by the process of FIGS. 1-7 or a process of FIGS. 11-17 (to be described later), wherein the photodiode IR is formed in the material layer 14 (such as silicon germanium (Si₁₋ₓGeₓ) or silicon carbide (Si_{1-y}C_{y}), wherein 0<x,y<1) having a different property from the substrate layer 11. The photodiodes R, G and B can be formed in the substrate 11 and not in the material layer 14, for example by a process of FIGS. 9-10. Referring to FIGS. 9-10, a well 24 is formed in the substrate 11 by an ion implantation step, and another well 28 having an opposite conductivity to the well 24 is formed by another ion implantation step, so that a PN junction is formed. Thus, a photodiode is formed. To better sense light with a desired wavelength, at a higher layer (not shown), a color filter (not shown) can be formed.

The sensor pixel unit including photodiodes for visible and invisible light wavelengths can be applied to many applications. In one example, the sensor pixel unit can be used in a proximity sensor. The proximity sensor for example includes an infrared light source and an infrared sensor array. The infrared sensor array includes plural infrared photodiodes IR. In another example, the sensor pixel unit can be used in an ambient light sensor. The ambient light sensor includes plural photodiodes for visible light, plural photodiodes for invisible light, and a processor circuit. The photodiodes for visible light and plural photodiodes for invisible light receive ambient light to generate a first signal and a second signal, respectively, and the processor circuit is adapted to process the first and second signals to generate an ambient light signal, for example by subtracting the second signal from the first signal. In another example, the sensor pixel unit can be used in a recognition device. The recognition device includes an infrared light source and an infrared sensor array (the infrared sensor array includes plural infrared photodiodes IR), and a processor circuit. The infrared sensor array receives infrared light projected from the infrared light source and reflected by an object processor circuit, and outputs a corresponding signal. The processor circuit is adapted to process the signal outputted from the infrared sensor array, and determine the size, distance and/or movement of the object thereby. The processor circuit outputs a recognition signal which includes distance information and/or gesture information that relates to the object.

FIGS. 11-17 illustrate another embodiment of the present invention. FIGS. 11-15 show steps similar to FIGS. 1-5. In FIG. 16, an N-well 18a is formed by ion implantation in the material layer 14, and a P-well is formed by ion implantation in the N-well 18a so as to form a photo diode 18. The N-well 18a can isolate the photodiode 18 to block any defect induced dark current from the material layer 14. FIG. 17 show steps similar to FIG. 7.

This embodiment is different from the embodiment of FIGS. 1-7 in that the additional N-well 18a further improves the performance of the photodiode.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, the materials and number of interconnection layers in the abovementioned example are for illustration only, and may be modified in many ways. As another example, the transistor is not limited to the CMOS transistor as shown, but may be bipolar junction transistor (BJT) or other devices. In view of the foregoing, the spirit of the present invention should cover all such and other modifications and variations, which should be interpreted to fall within the scope of the following claims and their equivalents.

1-8. (canceled)

9. A process for making an optoelectronic device, comprising:
providing a substrate made of a first material;
etching a region of the substrate;
filling the region with a second material different from the first material, by epitaxial growth;
forming an N-well in the region made of the second material, by implantation; and
forming a photo diode for a first wavelength in the region made of the second material, wherein the photo diode is formed by a PN junction, the PN junction being formed by P-type and N-type impurities, and the P-type and N-type impurities together having an upper boundary and a lower boundary, wherein the N-well is additional to the PN junction and the N-well is deeper than the lower boundary.

10. The process of claim 9, further comprising: forming an electronic circuit in another region of the substrate.

11. The process of claim 9, wherein the second material includes silicon germanium (Si₁₋ₓGeₓ) or silicon carbide (Si_{1-y}C_{y}), wherein 0<x,y<1.

12. (canceled)

13. The process of claim 9, further comprising: forming a masking layer to define the region before etching it.

14. The process of claim 13, further comprising: removing the masking layer after filling the region with the second material.

15. The process of claim 13, wherein the masking layer includes oxide.

16. The process of claim 9, wherein a light absorption efficiency of the photo diode to a light beam above 800 nm or below 450 nm is higher than a photo diode formed in silicon.

17. The process of claim 9, further comprising forming another photodiode for a second wavelength in the substrate and not in the region made of the second material.

18. The process of claim 17, wherein the first wavelength is an invisible light wavelength and the second wavelength is a visible light wavelength.
